(19) United States
(12) Patent Application Publication
(10) Pub. No.: US 2025/0172173 A1
(43) Pub. Date: May 29, 2025

(54) BRACKET, INSPECTION DEVICE, AND METHOD OF MANUFACTURING BRACKET

(71) Applicant: YOKOWO CO., LTD., Tokyo (JP)

(72) Inventors: Hirotaka TAKAHASHI, Tomioka-Shi (JP); Yayoi TOMARU, Tomioka-Shi (JP); Hiroshi KATO, Tomioka-Shi (JP)

(73) Assignee: YOKOWO CO., LTD., Tokyo (JP)

(21) Appl. No.: 18/959,710

(22) Filed: Nov. 26, 2024

(30) Foreign Application Priority Data
Nov. 28, 2023 (JP) 2023-200452

(51) Int. Cl. F16C 29/06; F16C 33/30; F16C 43/04

(52) U.S. Cl. CPC F16C 29/0638; F16C 33/30; F16C 43/04; F16C 2300/02

(57) ABSTRACT

A bracket includes a guide member, a moving member for moving a connector relative to the guide member, and a rolling element located between the guide member and the moving member. At least a part of the rolling element is embedded in a groove provided in the guide member.

### CROSS-REFERENCE TO RELATED APPLICATION

This application is based on Japanese patent application No. 2023-200452, filed Nov. 28, 2023, the content of which is incorporated hereinto by reference.

### BACKGROUND

### Technical Field

The present invention relates to a bracket, an inspection device, and a method of manufacturing a bracket.

### Related Art

In recent years, co-packaged optics (CPO) have been developed as a type of semiconductor device. The CPO is a device in which a chip for optical communication is mounted on a substrate. In the CPO, optical signals are used in addition to electrical signals in the related art as signals transmitted within the substrate.

Japanese Unexamined Patent Publication No. S62-30969 describes a connection between a connector of a fixture and a connector of a connection unit. An inspection object is placed on the fixture. The connection unit includes a unit main body, a movable member, and a toggle clamp. The movable member includes the connector. The unit main body and the movable member are movable toward the fixture by the toggle clamp. The connector provided in the movable member is connected to the connector of the fixture by the movement of the unit main body and the movable member.

### SUMMARY

A connector provided in a socket on which an inspection object is mounted and a connector provided in a bracket attached to the socket may be connected to each other. These sockets may be connected to each other as the connector provided in the bracket is moved toward the connector provided in the socket. A signal from a coaxial cable connected to the connector provided in the bracket is transmitted to the inspection object through the connectors connected to each other. When the connector provided in the bracket is moved to be connected to the connector provided in the socket, for example, the connector provided in the bracket needs to be aligned with the connector provided in the socket with high accuracy to reduce a signal transmission loss.

An example of an object of the present invention is to align a connector provided in a bracket with high accuracy. Other objects of the present invention will become apparent from the description of the present specification.

An aspect of the present invention is a bracket. The bracket includes a guide member, a moving member for moving a connector relative to the guide member, and a rolling element located between the guide member and the moving member. At least a part of the rolling element is embedded in a groove provided in the guide member.

An aspect of the present invention is an inspection device. The inspection device includes a socket for mounting an inspection object, and the bracket attached to the socket.

An aspect of the present invention is a method of manufacturing a bracket. The method includes assembling a guide member, a moving member for moving a connector relative to the guide member, and a rolling element located between the guide member and the moving member. The assembling the guide member, the moving member, and the rolling element includes aligning the moving member by aligning a jig attached to the moving member.

According to the above aspects of the present invention, the connector provided in the bracket can be aligned with high accuracy.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view of an inspection device according to an embodiment;

FIG. 2 is an exploded perspective view of a bracket according to the embodiment;

FIG. 3 is a cross-sectional view of a cross roller table according to the embodiment;

FIG. 4 is a plan view of the cross roller table according to the embodiment;

FIG. 5 is a view for describing an example of a method of manufacturing a bracket according to the embodiment;

FIG. 6 is a view for describing the example of the method of manufacturing a bracket according to the embodiment; and

FIG. 7 is a view for describing the example of the method of manufacturing a bracket according to the embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, an embodiment of the present invention will be described with reference to the drawings. In all drawings, the same constituent elements are denoted by the same reference numerals, and detailed description thereof will not be repeated.

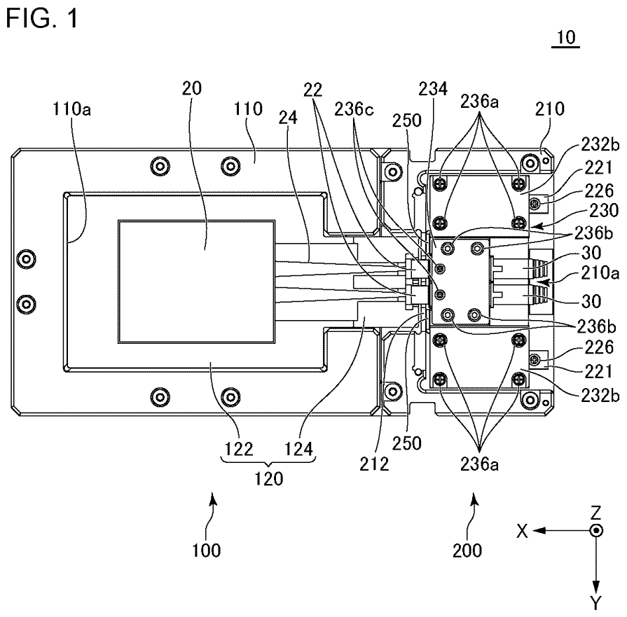

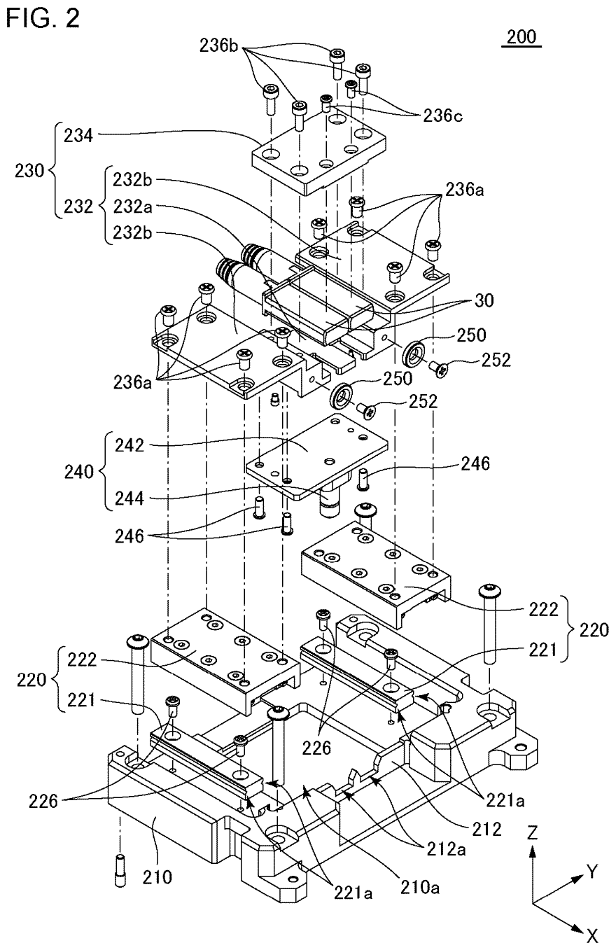

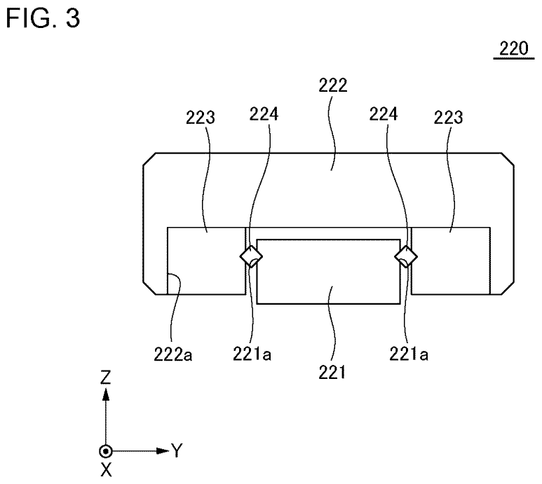

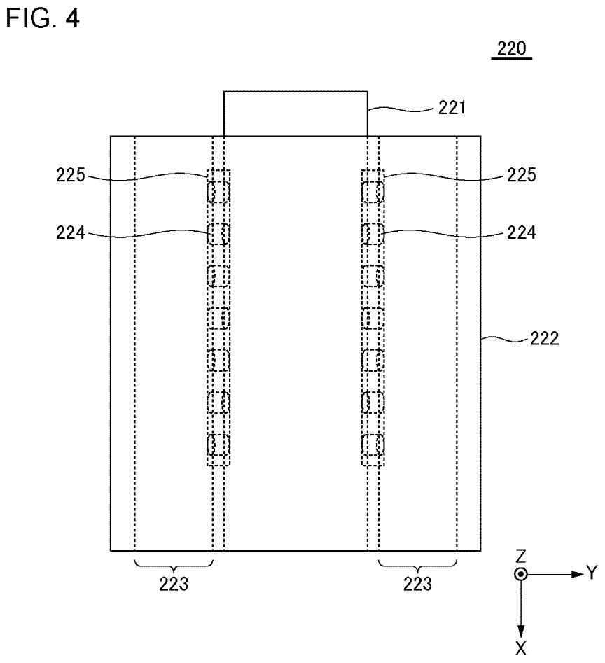

FIG. 1 is a plan view of an inspection device 10 according to the embodiment. FIG. 2 is an exploded perspective view of a bracket 200 according to the embodiment. FIG. 3 is a cross-sectional view of a cross roller table 220 according to the embodiment. FIG. 4 is a plan view of the cross roller table 220 according to the embodiment.

As shown in FIG. 1, the inspection device 10 according to the embodiment includes a socket 100 and the bracket 200. As shown in FIG. 1, the socket 100 includes a socket main body 110 and an inlay 120. As shown in FIG. 1, the inlay 120 includes an inlay main body 122 and an inlay protrusion 124. As shown in FIGS. 1 and 2, the bracket 200 includes a frame body 210, a pair of cross roller tables 220, a connector assembly 230, a cam follower assembly 240, and a pair of dampers 250. As shown in FIGS. 1 and 2, the frame body 210 defines an opening 210a. As shown in FIGS. 1 to 4, each cross roller table 220 includes a guide rail 221, a block 222, a pair of sliding rails 223, a plurality of rollers 224, and a pair of gauges 225. In FIG. 3, for the sake of description, the pair of gauges 225 are not shown. As shown in FIG. 2, the connector assembly 230 includes a first holding member 232 and a second holding member 234. As shown in FIG. 2, the cam follower assembly 240 includes a stage 242 and a cam follower 244.

For describing directions, an X direction, a Y direction, and a Z direction are defined. The Z direction is a direction parallel to a vertical direction. The X direction is one of horizontal directions perpendicular to the Z direction. The Y direction is one of the horizontal directions perpendicular to the Z direction and the X direction. In the embodiment, the X direction is a direction from a side where one of the socket 100 and the bracket 200 is located to a side where the other of the socket 100 and the bracket 200 is located. In FIGS. 1 and 4, a white circle with a black dot indicating the Z direction shows that an arrow of a Z axis points from a back to a front of the paper surface. In FIG. 3, a white circle with a black dot indicating the X direction shows that an arrow of an X axis points from the back to the front of the paper surface.

Hereinafter, as necessary, a side indicated by the arrow of the X axis is referred to as a +X side, a side opposite to the side indicated by the arrow of the X axis is referred to as a −X side, a side indicated by an arrow of a Y axis is referred to as a +Y side, a side opposite to the side indicated by the arrow of the Y axis is referred to as a −Y side, a side indicated by the arrow of the Z axis is referred to as a +Z side, and a side opposite to the side indicated by the arrow of the Z axis is referred to as a −Z side.

As shown in FIG. 1, when seen in the Z direction, the socket 100 and the bracket 200 are arranged in the X direction. In an example shown in FIG. 1, the socket 100 is located on the +X side with respect to the bracket 200, and the bracket 200 is located on the −X side with respect to the socket 100. The socket 100 and the bracket 200 are positioned with respect to each other by pins and are mechanically connected to each other by a mechanical connection method such as screwing. The disposition of the socket 100 and the bracket 200, however, is not limited to the example shown in FIG. 1.

As shown in FIG. 1, a semiconductor package 20, a pair of socket-side connectors 22, and a plurality of optical cables 24 are mounted on a +Z side surface side of the socket 100 via the inlay 120. The semiconductor package 20, the pair of socket-side connectors 22, and the optical cables 24 form co-packaged optics (CPO). As shown in FIGS. 1 and 2, a pair of bracket-side connectors 30 are provided in the bracket 200. Each socket-side connector 22 serves as a female connector to receive the corresponding bracket-side connector 30, and each bracket-side connector 30 serves as a male connector to be inserted into the socket-side connector 22. However, the socket-side connector 22 may serve as a male connector and the bracket-side connector 30 may serve as a female connector. In the example shown in FIG. 1, a −X side end portion of each socket-side connector 22 and a +X side end portion of the corresponding bracket-side connector 30 are connected to each other.

When the inspection device 10 is shipped, the semiconductor package 20, the pair of socket-side connectors 22, the plurality of optical cables 24, and the pair of bracket-side connectors 30 are usually removed from the inspection device 10. Hereinafter, unless otherwise specified, the inspection device 10 refers not only to an inspection device 10 including a semiconductor package 20, a pair of socket-side connectors 22, a plurality of optical cables 24, and a pair of bracket-side connectors 30, but also to an inspection device 10 not including a semiconductor package 20, a pair of socket-side connectors 22, a plurality of optical cables 24, and a pair of bracket-side connectors 30.

The socket main body 110 is made of, for example, a metal, a resin or a ceramic. As shown in FIG. 1, the socket main body 110 has a substantially rectangular shape with a pair of long sides substantially parallel to the X direction and a pair of short sides substantially parallel to the Y direction when seen in the Z direction. A shape of the socket main body 110, however, is not limited to the example shown in FIG. 1.

The inlay 120 is made of, for example, a resin, a plastic or a ceramic. As shown in FIG. 1, the inlay 120 is embedded in a socket groove 110a provided on a +Z side surface of the socket main body 110. The inlay main body 122 is located at a substantially center portion of the socket main body 110 in the X direction and the Y direction when seen in the Z direction. As shown in FIG. 1, the inlay main body 122 has a substantially rectangular shape with a pair of long sides substantially parallel to the X direction and a pair of short sides substantially parallel to the Y direction when seen in the Z direction. A shape of the inlay main body 122, however, is not limited to the example shown in FIG. 1. The semiconductor package 20 is mounted on a +Z side surface side of the inlay main body 122. The inlay protrusion 124 protrudes from the side of the inlay main body 122 on the −X side toward the bracket 200. A −X side end portion of the inlay protrusion 124 and a portion of the frame body 210 located on the +X side with respect to the opening 210a overlap each other in the Z direction. The pair of socket-side connectors 22 are mounted on a +Z side surface side of the −X side end portion of the inlay protrusion 124. The semiconductor package 20 and the pair of socket-side connectors 22 are optically coupled to each other through the plurality of optical cables 24. The plurality of optical cables 24 are mounted on the +Z side surface side of the inlay 120 from one to the other of the inlay main body 122 and the inlay protrusion 124. Accordingly, the semiconductor package 20, the pair of socket-side connectors 22, and the plurality of optical cables 24 can be integrally mounted on a +Z side surface side of the socket main body 110 by embedding the inlay 120 in the socket groove 110a with the plurality of optical cables 24 held on the +Z side surface side of the inlay 120.

In the embodiment, the semiconductor package 20 serves as an inspection object of the inspection device 10. The semiconductor package 20 is optically coupled to an external device of the inspection device 10 through the plurality of optical cables 24, the pair of socket-side connectors 22, and the pair of bracket-side connectors 30. Furthermore, the semiconductor package 20 is electrically connected to an unillustrated inspection substrate in the inspection device 10 through an unillustrated probe provided inside the socket 100.

The frame body 210 is made of, for example, a metal. As shown in FIGS. 1 and 2, when seen in the Z direction, the frame body 210 has a substantially rectangular frame shape with a pair of short sides substantially parallel to the X direction and a pair of long sides substantially parallel to the Y direction. A shape of the frame body 210, however, is not limited to the examples shown in FIGS. 1 and 2.

Each guide rail 221 is made of, for example, a metal. As shown in FIGS. 1 and 2, when seen in the Z direction, the pair of guide rails 221 are located on opposite sides of the opening 210a in the Y direction. As shown in FIG. 2, each guide rail 221 extends in the X direction. Both end portions in the X direction of the +Y side guide rail 221 and a portion of the frame body 210 on the +Y side of the opening 210a are fixed to each other by screwing a pair of rail attachment screws 226. Both end portions in the X direction of the −Y side guide rail 221 and a portion of the frame body 210 on the −Y side of the opening 210a are fixed to each other by screwing another pair of rail attachment screws 226.

Each block 222 is made of, for example, a metal. As shown in FIG. 2, each block 222 has a substantially rectangular shape with a pair of long sides substantially parallel to the X direction and a pair of short sides substantially parallel to the Y direction when seen in the Z direction. A shape of each block 222 is not limited to the example shown in FIG. 2. As shown in FIG. 3, a block groove 222a is provided on a −Z side surface of each block 222. As shown in FIG. 3, when seen in the X direction, the pair of sliding rails 223 are provided on opposite inner side surfaces of the block groove 222a in the Y direction. Each sliding rail 223 is made of, for example, a metal. The block 222 and the pair of sliding rails 223 are fixed to each other by screwing. The block 222 and the pair of sliding rails 223 are integrally slidable relative to the guide rail 221 in the X direction. Accordingly, the guide rail 221 serves as a guide member to guide the block 222 and the pair of sliding rails 223 in the X direction. The block 222 and the pair of sliding rails 223 serve as moving members for moving the bracket-side connector 30 relative to the guide rail 221 with the block 222 and the connector assembly 230 attached to each other.

As shown in FIGS. 3 and 4, the plurality of rollers 224 are disposed between the +Y side lateral surface of the guide rail 221 and the −Y side lateral surface of the +Y side sliding rail 223. Hereinafter, as necessary, the roller 224 disposed between the +Y side lateral surface of the guide rail 221 and the −Y side lateral surface of the +Y side sliding rail 223 is referred to as a +Y side roller 224. The +Y side roller 224 is made of, for example, a metal. As shown in FIG. 4, a plurality of the +Y side rollers 224 are integrally held along the guide rail 221 by the +Y side gauge 225 extending in the X direction. In examples shown in FIGS. 3 and 4, the +Y side rollers 224 having a rotation axis inclined by approximately 45° toward the Y direction with respect to the Z direction and the +Y side rollers 224 having a rotation axis inclined by approximately −45° toward the Y direction with respect to the Z direction are alternately arranged in the X direction. The +Y side roller 224 serves as a rolling element to roll between the +Y side lateral surface of the guide rail 221 and the −Y side lateral surface of the +Y side sliding rail 223. However, a ball may be used as the rolling element instead of the roller 224.

As shown in FIGS. 3 and 4, a plurality of rollers 224 are disposed between the −Y side lateral surface of the guide rail 221 and the +Y side lateral surface of the −Y side sliding rail 223. Hereinafter, as necessary, the roller 224 disposed between the −Y side lateral surface of the guide rail 221 and the +Y side lateral surface of the −Y side sliding rail 223 is referred to as a −Y side roller 224. The −Y side roller 224 is made of, for example, a metal. As shown in FIG. 4, a plurality of the −Y side rollers 224 are integrally held along the guide rail 221 by the −Y side gauge 225 extending in the X direction. In the examples shown in FIGS. 3 and 4, the −Y side rollers 224 having a rotation axis inclined by approximately 45° toward the Y direction with respect to the Z direction and the −Y side rollers 224 having a rotation axis is inclined by approximately −45° toward the Y direction with respect to the Z direction are alternately arranged in the X direction. The −Y side roller 224 serves a rolling element to roll between the −Y side lateral surface of the guide rail 221 and the +Y side lateral surface of the −Y side sliding rail 223. However, a ball may be used as the rolling element instead of the roller 224.

As shown in FIGS. 2 and 3, a pair of rail grooves 221a are provided on opposite side surfaces of each guide rail 221 in the Y direction. As shown in FIG. 2, each rail groove 221a extends in the X direction. As shown in FIG. 3, at least a part of the +Y side roller 224 and at least a part of the −Y side roller 224 are embedded in the +Y side rail groove 221a and the −Y side rail groove 221a respectively. Accordingly, a contact area between the guide rail 221 and the roller 224 can be increased compared to when using a linear bushing having a shaft without a groove corresponding to the rail groove 221a instead of the guide rail 221. Thus, an allowable load of the cross roller table 220 can be increased compared to when using the linear bushing.

As shown in FIGS. 1 and 2, the first holding member 232 includes a base 232a and a pair of attachment plates 232b. The base 232a defines a groove for accommodating the pair of bracket-side connectors 30. The pair of attachment plates 232b are located on opposite sides of the base 232a in the Y direction. The base 232a and the pair of attachment plates 232b are, for example, integrally molded metal. As shown in FIGS. 1 and 2, each attachment plate 232b has a substantially rectangular shape with a pair of long sides substantially parallel to the X direction and a pair of short sides substantially parallel to the Y direction. A shape of each attachment plate 232b, however, is not limited to the examples shown in FIGS. 1 and 2. As shown in FIGS. 1 and 2, each attachment plate 232b and the corresponding block 222 are fixed to each other by screwing a plurality of first assembly screws 236a. Accordingly, the pair of blocks 222 and the first holding member 232 are integrally slidable in the X direction relative to the pair of guide rails 221. In the examples shown in FIGS. 1 and 2, four first assembly screws 236a are provided at four corner portions of each attachment plate 232b. The number and disposition of the first assembly screws 236a, however, are not limited to the examples shown in FIGS. 1 and 2.

The second holding member 234 is made of, for example, a metal. As shown in FIGS. 1 and 2, the second holding member 234 covers +Z side surfaces of the pair of bracket-side connectors 30. As shown in FIGS. 1 and 2, the second holding member 234 has a substantially rectangular shape with a pair of short sides substantially parallel to the X direction and a pair of long sides substantially parallel to the Y direction. A shape of the second holding member 234, however, is not limited to the example shown in FIG. 2. The second holding member 234 and the base 232a are fixed to each other by screwing a plurality of second assembly screws 236b. Accordingly, the first holding member 232 and the second holding member 234 are integrated as the connector assembly 230 to serve as a holding member for holding the pair of bracket-side connectors 30. In the examples shown in FIGS. 1 and 2, four second assembly screws 236b are provided at four corner portions of the second holding member 234. The number and arrangement of the second assembly screws 236b, however, are not limited to the examples shown in FIGS. 1 and 2.

As shown in FIGS. 1 and 2, two pressing screws 236c are screwed onto a +X side end portion of the second holding member 234. A −Z side end portion of each pressing screw 236c protrudes from a −Z side surface of the second holding member 234 toward the −Z side and presses the +Z side surface of the bracket-side connector 30. Thus, rattling of the bracket-side connector 30 can be suppressed by the pressing screw 236c. The number and disposition of the pressing screws 236c, however, are not limited to the examples shown in FIGS. 1 and 2.

As shown in FIG. 2, the stage 242 has a substantially rectangular shape with a pair of long sides substantially parallel to the X direction and a pair of short sides substantially parallel to the Y direction when seen in the Z direction. A shape of the stage 242, however, is not limited to the example shown in FIG. 2. As shown in FIG. 2, the stage 242 is attached to a −Z side surface of the base 232a. As shown in FIG. 2, the base 232a and the stage 242 are fixed to each other by screwing a plurality of stage attachment screws 246. In the example shown in FIG. 2, four stage attachment screws 246 are provided at four corner portions of the stage 242. The number and disposition of the stage attachment screws 246, however, are not limited to the example shown in FIG. 2.

As shown in FIG. 2, the cam follower 244 protrudes from a −Z side surface of the stage 242 toward the −Z side and extends in the Z direction. The pair of blocks 222, the connector assembly 230, the stage 242, and each bracket-side connector 30 can be moved integrally in the X direction by pressing a −Z side end portion of the cam follower 244 toward the +X side or the −X side using an unillustrated actuator arm. Instead of the cam follower 244, the bracket 200 may have a simple shaft body protruding from the −Z side surface of the stage 242 toward the −Z side and extending in the Z direction.

As shown in FIGS. 1 and 2, the frame body 210 has a partition wall 212 located on the +X side with respect to the opening 210a. As shown in FIG. 1, the partition wall 212 is located between the −X side end portion of the inlay protrusion 124 and a +X side end portion of the connector assembly 230. Accordingly, the partition wall 212 serves as a restricting member to restrict movement of the pair of blocks 222, the connector assembly 230, the cam follower assembly 240, and each bracket-side connector 30 to the +X side. As shown in FIG. 2, the partition wall 212 is notched by a pair of notched grooves 212a open toward the +Z side. As shown in FIGS. 1 and 2, the pair of notched grooves 212a are provided in portions of the partition wall 212 opposed to the +X side end portions of the pair of bracket-side connectors 30. As shown in FIG. 1, the −X side end portions of the pair of socket-side connectors 22 enter the pair of notched grooves 212a. The partition wall 212 may be notched by a hole penetrating the partition wall 212 in the X direction instead of a groove such as the notched groove 212a. Each socket-side connector 22 can enter not only into the notched groove 212a but also into the hole penetrating the partition wall 212 in the X direction.

As shown in FIGS. 1 and 2, the pair of dampers 250 are attached to a +X side end surface of the base 232a. As shown in FIG. 2, the pair of dampers 250 and the base 232a are fixed to each other by screwing damper attachment screws 252. In the embodiment, each damper 250 is made of a super engineering plastic such as polyether ether ketone (PEEK). Each damper 250, however, may be configured by an elastic member such as a spring. In the embodiment, a +X side surface of each damper 250 and a −X side surface of the partition wall 212 contact with each other when each bracket-side connector 30 is moved toward the corresponding socket-side connector 22 to connect the socket-side connector 22 and the bracket-side connector 30 to each other. Accordingly, the impact of contact between each socket-side connector 22 and the corresponding bracket-side connector 30 is cushioned by the corresponding damper 250. Thus, damage to each socket-side connector 22 and the corresponding bracket-side connector 30 on connecting the socket-side connector 22 and the bracket-side connector 30 can be suppressed compared to when the damper 250 is not provided. A position where the damper 250 is provided is not limited to the examples shown in FIGS. 1 and 2. For example, the damper 250 may be provided on the −X side surface of the partition wall 212 instead of the +X side end surface of the base 232a.

Next, the embodiment and a comparative example are compared to describe functions of the cross roller table 220 according to the embodiment. In the comparative example, a linear bushing is used instead of the cross roller table 220. Instead of the guide rail 221 of the embodiment, the linear bushing according to the comparative example has a shaft without a groove corresponding to the rail groove 221a.

In the embodiment, the −Z side end portion of the cam follower 244 is pressed toward the +X side by the unillustrated actuator arm to move the bracket-side connector 30 toward the socket 100 so that each socket-side connector 22 and the corresponding bracket-side connector 30 are connected to each other. The pressing the −Z side end portion of the cam follower 244 toward the +X side, however, generates a moment to rotate the cam follower 244 clockwise when seen from the +Y side. When the cam follower 244 is rotated clockwise when seen from the +Y side, each bracket-side connector 30 is also rotated clockwise when seen from the +Y side. When each bracket-side connector 30 is rotated clockwise when seen from the +Y side, the +X side end portion of each bracket-side connector 30 and the −X side end portion of the corresponding socket-side connector 22 do not directly face each other in the X direction. The +X side end portion of each bracket-side connector 30 and the −X side end portion of the corresponding socket-side connector 22 not directly facing each other in the X direction make it difficult to align the +X side end portion of each bracket-side connector 30 with the −X side end portion of the corresponding socket-side connector 22 with high accuracy. The failure to align the +X side end portion of each bracket-side connector 30 with the −X side end portion of the corresponding socket-side connector 22 with high accuracy may make it difficult to ensure a good connection between each socket-side connector 22 and the corresponding bracket-side connector 30.

As described above, in the embodiment, as shown in FIG. 3, at least a part of the roller 224 is embedded in the rail groove 221a. Accordingly, the contact area between the guide rail 221 and the roller 224 can be increased in the embodiment compared to the comparative example. Thus, the allowable load and an allowable moment of the block 222 can be increased in the embodiment compared to the comparative example. Accordingly, the cam follower 244 can be less likely to be rotated clockwise when seen from the +Y side in the embodiment compared to the comparative example even when the −Z side end portion of the cam follower 244 is pressed toward the +X side to generate a moment to rotate the cam follower 244 clockwise when seen from the +Y side. Thus, the +X side end portion of each bracket-side connector 30 can be aligned with the −X side end portion of the corresponding socket-side connector 22 with high accuracy in all directions, including the X direction, the Y direction, and the Z direction in the embodiment compared to the comparative example.

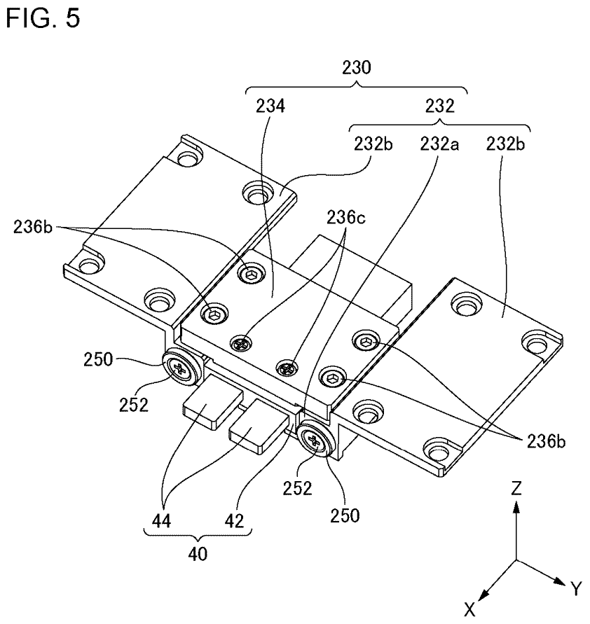

FIGS. 5 to 7 are views for describing an example of a method of manufacturing the bracket 200 according to the embodiment. In examples shown in FIGS. 5 to 7, the bracket 200 is manufactured by assembling the frame body 210, the pair of cross roller tables 220, the connector assembly 230, the cam follower assembly 240, and the pair of dampers 250 as follows.

First, as shown in FIG. 5, a jig 40 is held by the connector assembly 230. In the example shown in FIG. 5, the jig 40 includes a jig main body 42 and a pair of jig protrusions 44. In the example shown in FIG. 5, first, the jig main body 42 is accommodated in the base 232a with the pair of jig protrusions 44 protruding toward the +X side with respect to the +X side end surface of the base 232a. Next, the first holding member 232 and the second holding member 234 are fixed to each other by screwing the plurality of second assembly screws 236b. Next, the plurality of pressing screws 236c are screwed onto the second holding member 234 to cause the −Z side end portion of each pressing screw 236c to press a +Z side surface of the jig main body 42 toward the −Z side. Accordingly, the jig main body 42 can be prevented from rattling by the pressing screws 236c. In the example shown in FIG. 5, the pair of dampers 250 are fixed to the +X side end surface of the base 232a by screwing the pair of damper attachment screws 252.

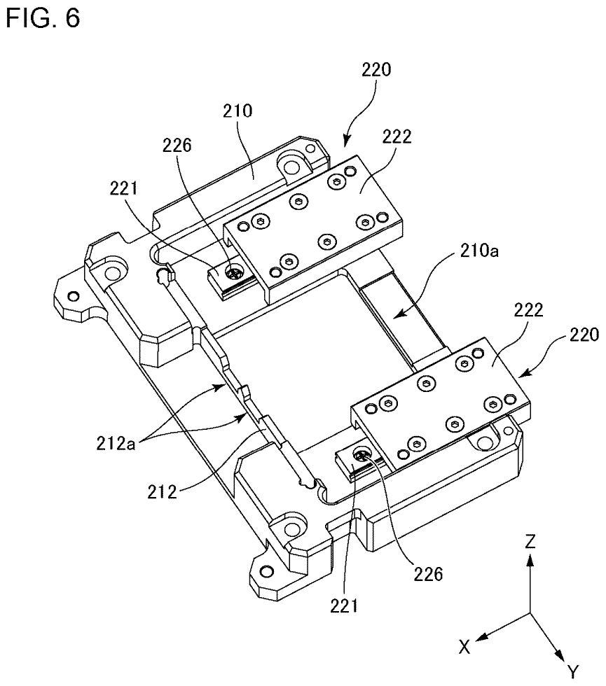

Next, as shown in FIG. 6, the frame body 210 and the pair of cross roller tables 220 are temporarily fixed to each other by temporarily fastening a plurality of the rail attachment screws 226. In the example shown in FIG. 6, while each block 222 is moved to the −X side to expose a +X side end portion of each guide rail 221, the +X side end portion of each guide rail 221 and a portion of the frame body 210 overlapping the +X side end portion of each guide rail 221 in the Z direction are temporarily fixed by temporarily fastening the rail attachment screws 226. Next, while each block 222 is moved to the +X side to expose a −X side end portion of each guide rail 221, the −X side end portion of each guide rail 221 and a portion of the frame body 210 overlapping the −X side end portion of each guide rail 221 in the Z direction are temporarily fixed by temporarily fastening the rail attachment screws 226.

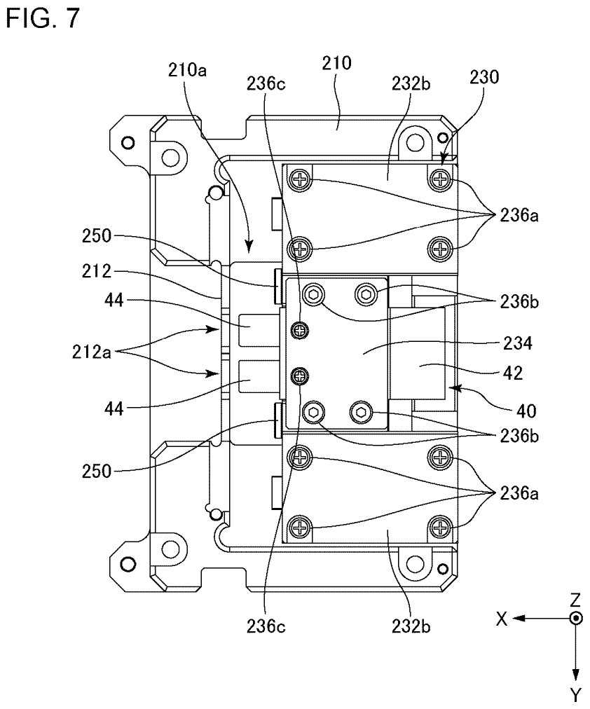

Next, as shown in FIG. 7, the pair of blocks 222 and the pair of second holding members 234 are fixed to each other by screwing the plurality of first assembly screws 236a. The jig 40 is attached to the pair of blocks 222 via the connector assembly 230 by the fixing of the pair of blocks 222 and the pair of second holding members 234.

Next, the pair of jig protrusions 44 is aligned by entering the pair of jig protrusions 44 into the pair of notched grooves 212a. The pair of cross roller tables 220 and the connector assembly 230 are aligned by aligning the pair of jig protrusions 44. The partition wall 212 may be notched by a hole penetrating the partition wall 212 in the X direction instead of a groove such as the notched groove 212a. The pair of jig protrusions 44 can also be aligned by the hole in the same manner as the notched groove 212a.

Next, the frame body 210 and the pair of guide rails 221 are fixed to each other by main fastening of the plurality of rail attachment screws 226 while the pair of cross roller tables 220 and the connector assembly 230 are aligned by the alignment of the jig 40. Positions of the pair of cross roller tables 220 and the connector assembly 230 in the Z direction are determined by the fixing of the frame body 210 and the pair of guide rails 221.

Next, the second holding member 234 is removed from the first holding member 232 by removing the plurality of second assembly screws 236b, and the jig 40 is removed from the first holding member 232. Next, the first holding member 232 and the second holding member 234 are fixed to each other again by screwing the plurality of second assembly screws 236b. Next, the connector assembly 230 and the cam follower assembly 240 are fixed to each other by screwing the plurality of stage attachment screws 246. When the first holding member 232 and the second holding member 234 are fixed to each other again, the connector assembly 230 may not hold the pair of bracket-side connectors 30. For example, the bracket 200 is shipped with the connector assembly 230 not holding the bracket-side connector 30.

In the embodiment, the bracket-side connector 30 is guided in the X direction by the pair of cross roller tables 220 disposed parallel to each other. Thus, the failure to accurately dispose the pair of cross roller tables 220 parallel to each other in the X direction may make it difficult to smoothly guide the connector assembly 230 in the X direction. In the embodiment, however, the pair of cross roller tables 220 and the connector assembly 230 are aligned by the alignment of the jig 40. Accordingly, the pair of cross roller tables 220 can be accurately disposed parallel to each other in the X direction compared to when the jig 40 is not used. The pair of cross roller tables 220 accurately disposed parallel to each other in the X direction enables the +X side end portion of each bracket-side connector 30 to be aligned with the −X side end portion of the corresponding socket-side connector 22 with high accuracy in all directions, including the X direction, the Y direction, and the Z direction.

Furthermore, in the embodiment, the +X side end portion of each bracket-side connector 30 can be aligned with the −X side end portion of the corresponding socket-side connector 22 without the need to enable each bracket-side connector 30 to slightly move in the Y direction by a mechanical element such as a spring. Accordingly, durability of the bracket 200 can be improved compared to when the mechanical element is used.

Furthermore, in the embodiment, the frame body 210 and a set of the pair of cross roller tables 220 and the connector assembly 230 are aligned by the alignment of the jig 40 while the frame body 210 and the pair of guide rails 221 are temporarily fixed. Accordingly, the frame body 210 and the set of the pair of cross roller tables 220 and the connector assembly 230 can be aligned by moving the pair of blocks 222 and the connector assembly 230 in the X direction to enter the pair of jig protrusions 44 into the pair of notched grooves 212a with the frame body 210 and the pair of guide rails 221 temporarily fixed. Thus, the alignment of the frame body 210 with the set of the pair of cross roller tables 220 and the connector assembly 230 can be facilitated with flexibility compared to when the frame body 210 and the set of the pair of cross roller tables 220 and the connector assembly 230 are aligned after fixing the frame body 210 and the pair of guide rails 221 by main tightening of the multiple rail attachment screws 226.

Hitherto, the embodiment of the present invention has been described above with reference to the drawings, but these are examples of the present invention, and various configurations other than the above description can be adopted.

For example, a guide device for guiding the bracket-side connector 30 is not limited to the cross roller table 220 according to the embodiment. For example, the guide device may be a linear guide having a rolling element circulating along a circulation path provided inside the guide device. In the linear guide as well, at least a part of the rolling element is embedded in a groove provided in a guide rail. Accordingly, as described in the embodiment, the +X side end portion of each bracket-side connector 30 can be aligned with the −X side end portion of the corresponding socket-side connector 22 with high accuracy in all directions, including the X direction, the Y direction, and the Z direction compared to when the linear bushing is used.

The inspection object mounted on the socket 100 is not limited to the CPO and may be a semiconductor package without an optical element. The connector provided in the bracket 200 may be an electrical connector electrically connected to the inspection object mounted on the inspection device 10, instead of an optical connector optically coupled to the inspection object mounted on the socket 100.

According to the present specification, a bracket, an inspection device, and a method of manufacturing a bracket having the following aspects are provided.

### First Aspect

In a first aspect, a bracket includes a guide member, a moving member for moving a connector relative to the guide member, and a rolling element located between the guide member and the moving member. At least a part of the rolling element is embedded in a groove provided in the guide member.

The “guide member” corresponds to the “guide rail” of the embodiment described above. The “moving member” corresponds to the “block” and the “sliding rail” of the embodiment described above. The “rolling element” corresponds to the “roller” of the embodiment described above.

According to the above-described aspect, a contact area between the guide member and the rolling element can be increased compared to when using a linear bushing having a shaft not provided with a groove instead of the guide member. Accordingly, an allowable moment of the moving member can be increased compared when the linear bushing is used. Thus, the connector can be less likely to be rotated upon moving the connector by the moving member compared to when the linear bushing is used. Accordingly, the connector can be aligned with high accuracy compared to when the linear bushing is used.

### Second Aspect

In a second aspect, the bracket further includes a damper for cushioning impact of contact between the connector and another connector to be connected to the connector.

According to the above-described aspect, damage to the connector and the other connector on connecting the connector and the other connector can be suppressed compared to when the damper is not provided.

### Third Aspect

In a third aspect, the bracket further includes a partition wall to restrict movement of the moving member toward a side where another connector to be connected to the connector is located. A portion of the partition wall opposed to the connector is notched.

According to the above-described aspect, jig provided in the moving member can be aligned by entering at least a part of the jig into the notched portion of the partition wall. The connector can be aligned with high accuracy by aligning the moving member through the alignment of the jig.

### Fourth Aspect

In a fourth aspect, an inspection device includes a socket for mounting an inspection object, and the bracket attached to the socket.

In the fourth aspect, as in the first aspect, the connector can be aligned with high accuracy compared to when the linear bushing is used.

### Fifth Aspect

In a fifth aspect, a method of manufacturing a bracket, includes assembling a guide member, a moving member for moving a connector relative to the guide member, and a rolling element located between the guide member and the moving member. The assembling the guide member, the moving member, and the rolling element includes aligning the moving member by aligning a jig attached to the moving member.

The “guide member” corresponds to the “guide rail” of the embodiment described above. The “moving member” corresponds to the “block” and the “sliding rail” of the embodiment described above. The “rolling element” corresponds to the “roller” of the embodiment described above.

According to the above-described aspect, the connector can be aligned with high accuracy compared to when the moving members is not aligned.

### Sixth Aspect

In a sixth aspect, the assembling the guide member, the moving member, and the rolling element further includes temporarily fixing the guide member.

According to the sixth aspect, the moving member can be aligned by moving the moving member to align the jig with the guide member temporarily fixed. Accordingly, the alignment of the moving member can be facilitated with flexibility compared to when the moving member is aligned after fixing the guide member.

It is apparent that the present invention is not limited to the above embodiment, and may be modified and changed without departing from the scope and spirit of the invention.

### REFERENCE NUMERALS

10 inspection device, 20 semiconductor package, 22 socket-side connector, 24 optical cable, 30 bracket-side connector, 40 jig, 42 jig main body, 44 jig protrusion, 100 socket, 110 socket main body, 110a socket groove, 120 inlay, 122 inlay main body, 124 inlay protrusion, 200 bracket, 210 frame body, 210a opening, 212 partition wall, 212a notched groove, 220 cross roller table, 221 guide rail, 221a rail groove, 222 block, 222a block groove, 223 sliding rail, 224 roller, 225 gauge, 226 rail attachment screw, 230 connector assembly, 232 first holding member, 232a base, 232b attachment plate, 234 second holding member, 236a first assembly screw, 236b second assembly screw, 236c pressing screw, 240 cam follower assembly, 242 stage, 244 cam follower, 246 stage attachment screw, 250 damper, 252 damper attachment screw

What is claimed is:

1. A bracket comprising:
a guide member;
a moving member for moving a connector relative to the guide member; and
a rolling element located between the guide member and the moving member,
wherein at least a part of the rolling element is embedded in a groove provided in the guide member.

2. The bracket according to claim 1, further comprising:
a damper for cushioning impact of contact between the connector and another connector to be connected to the connector.

3. The bracket according to claim 1, further comprising:
a partition wall to restrict movement of the moving member toward a side where another connector to be connected to the connector is located,
wherein a portion of the partition wall opposed to the connector is notched.

4. An inspection device comprising:
a socket for mounting an inspection object; and
the bracket according to claim 1, the bracket being attached to the socket.

5. A method of manufacturing a bracket, comprising:
assembling a guide member, a moving member for moving a connector relative to the guide member, and a rolling element located between the guide member and the moving member,
wherein the assembling the guide member, the moving member, and the rolling element includes aligning the moving member by aligning a jig attached to the moving member.

6. The method of manufacturing a bracket according to claim 5,
wherein the assembling the guide member, the moving member, and the rolling element further includes temporarily fixing the guide member.
